(19) United States
(12) Patent Application Publication
(10) Pub. No.: US 2015/0075754 A1
(43) Pub. Date: Mar. 19, 2015

(54) SINGLE-PASS COLD PLATE ASSEMBLY

(71) Applicant: GE Aviation Systems LLC, Grand Rapids, MI (US)

(72) Inventors: Michel Engelhardt, Woodbury, NY (US); Paul Otto Stehlik, Northport, NY (US); Kerry Liu, Bayside, NY (US); Hanif Ramzan Sebro, Freeport, NY (US)

(73) Assignee: GE Aviation Systems LLC, Grand Rapids, MI (US)

(21) Appl. No.: 14/029,256

(22) Filed: Sep. 17, 2013

(51) Int. Cl. H05K 7/20; F28D 15/04; F28F 13/06

(52) U.S. Cl. CPC H05K 7/20254; F28F 13/06; F28D 15/04; H05K 7/20436; H05K 7/20509
USPC 165/104.26; 165/104.28; 165/109.1; 165/104.33

(57) ABSTRACT

A single-pass cold plate assembly having a base and a cover arranged in confronting relationship to define a cold plate with a spiral channel and a manifold with the manifold having a manifold inlet and a manifold outlet and where coolant may be introduced into the manifold inlet and may complete a single pass through the cold plate assembly.

### BACKGROUND OF THE INVENTION

Contemporary high power dissipating electronics produce heat that may result in thermal management problems. Heat must be removed from the electronic device to improve reliability and prevent premature failure of the electronics. Heat exchangers or heat sinks may be employed to dissipate the heat generated by the electronics; however, the beneficial functions may be contrary to maintaining or reducing the weight of the product or reducing its cost.

### BRIEF DESCRIPTION OF THE INVENTION

In one aspect, an embodiment of the invention relates to a single-pass cold plate assembly having a base and a cover arranged in confronting relationship to define a cold plate, a spiral channel having at least a portion provided in one of the base and cover, with a channel inlet located in a central portion of the one of the base and cover, and a channel outlet located at a periphery of the one of the base and cover, and a manifold provided in the other of the base and cover, with the manifold having a manifold inlet located on a periphery of the other of the base and cover, and a manifold outlet located in a central portion of the other of the base and cover and in fluid communication with the channel inlet, wherein coolant introduced into the manifold inlet may travel through the manifold, out the manifold outlet, into the channel inlet, where it moves through the spiral channel and out the channel outlet to complete a single pass through the cold plate assembly.

### BRIEF DESCRIPTION OF THE DRAWINGS

In the drawings:

FIG. 1 is a perspective view of a single-pass cold plate assembly according to the embodiment of the invention;

FIG. 2 is an exploded perspective view of the single-pass cold plate assembly of FIG. 1;

FIG. 3 is a perspective view of the single-pass cold plate assembly of FIG. 1 with electronic devices and coolant lines attached thereto;

FIG. 4 is a side view illustrating the single-pass cold plate assembly of FIG. 3;

FIG. 5 illustrates the flow path of a coolant within the single-pass cold plate assembly of FIG. 1;

FIG. 6 is an exploded perspective view of a single-pass cold plate assembly according to another embodiment of the invention;

FIG. 7 is a perspective view of the single-pass cold plate assembly of FIG. 6;

FIG. 8 is a top view of the single-pass cold plate assembly of FIG. 6; and

FIG. 9 is a side view illustrating the single-pass cold plate assembly of FIG. 6 with an electronics device and coolant lines attached thereto.

### DESCRIPTION OF EMBODIMENTS OF THE INVENTION

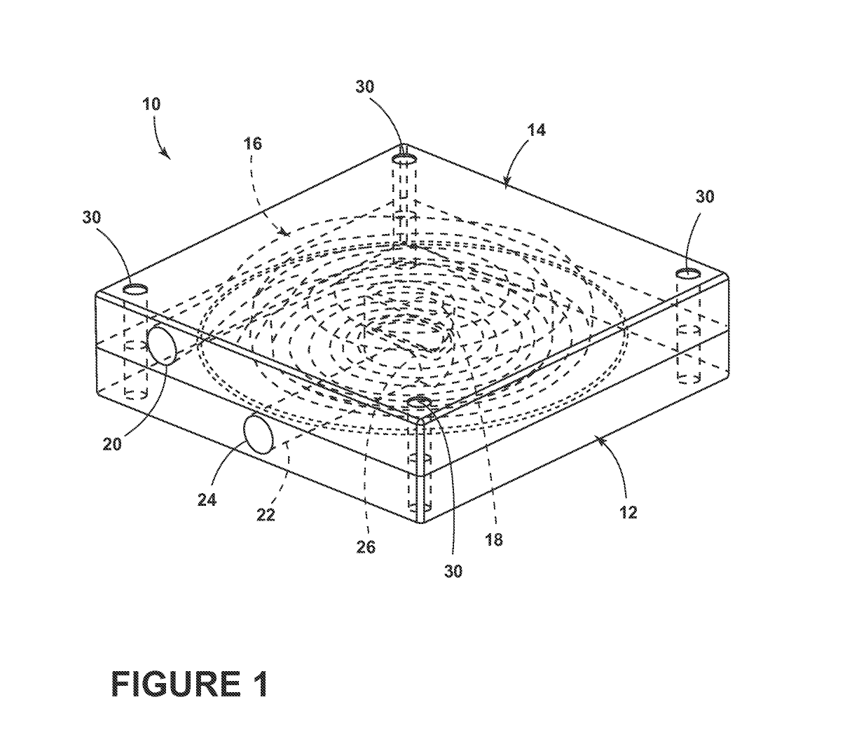

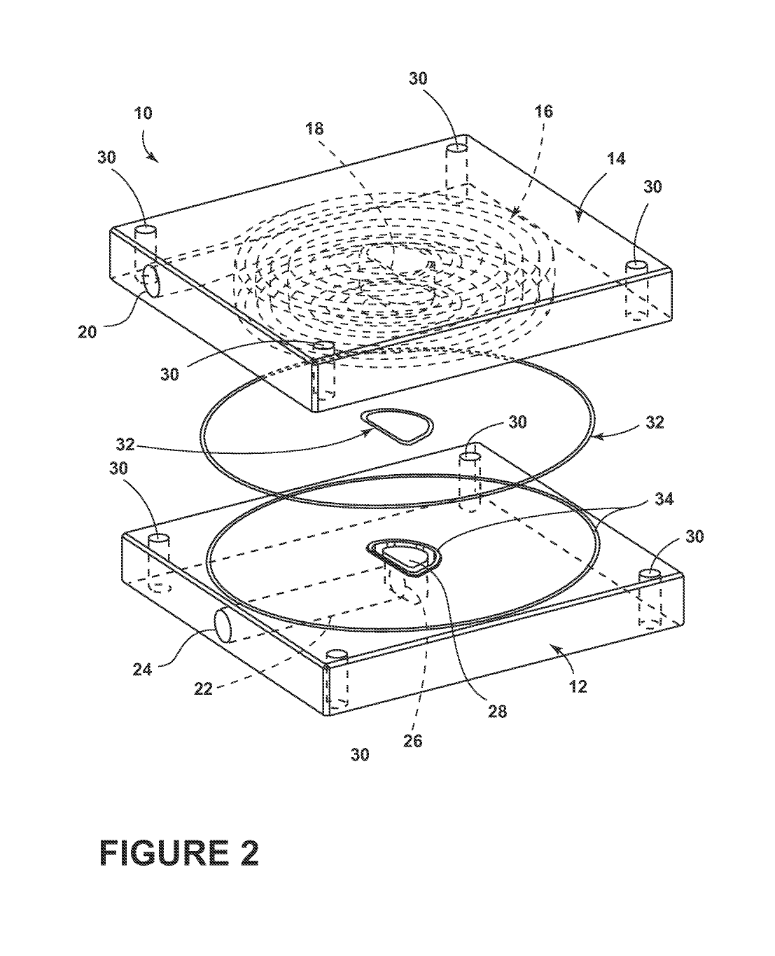

FIG. 1 illustrates a single-pass cold plate assembly 10 having a base 12 and a cover 14 that may be arranged in confronting relationship to define a cold plate, for example the base and cover may be mated to form the cold plate. A spiral channel 16 having a channel inlet 18 and a channel outlet 20, a manifold 22 having a manifold inlet 24, a manifold outlet 26, and a reservoir 28 (more clearly seen in FIG. 2) are also illustrated as being included in the single-pass cold plate assembly 10. The base 12 and cover 14 may be fastened together in any suitable manner. In the illustrated example, the base 12 and cover 14 have been illustrated as including openings 30 in which screws, not illustrated, may be inserted to fasten the base 12 and cover 14. Alternatively, other methods for fastening may also be used including the use of an adhesive or brazing. In the case of an adhesive, a thermally conductive compound may be used to bond the base 12 and the cover 14. The use of such a thermally conductive compound may minimize any thermal stresses that would be induced during production of the single-pass cold plate assembly 10 as compared to other means of fastening. While the base 12 and cover 14 have been illustrated in a square configuration, it is understood that they may take alternative forms including circular, rectangular, etc. The single-pass cold plate assembly 10 may be formed in any suitable manner including machining it from a solid metal blank. For example, the single-pass cold plate assembly 10 may be machined from aluminum or another metal depending on the thermal requirements.

The spiral channel 16 may have at least a portion provided in one of the base 12 and cover 14 while the manifold 22 may be provided in the other of the base 12 and cover 14. As may more clearly be seen in the exploded view of FIG. 2, the spiral channel 16 has been illustrated as being at least partially provided within the cover 14 and the manifold has been illustrated as being provided within the base 12. Although this need not be the case.

In the illustrated example, the channel inlet 18 may be located in a central portion of the cover 14 and the channel outlet 20 may be off-set and located on the edge periphery of the cover 14. It may be understood that the spiral channel 16 does not need to be a circular spiral or a perfect spiral. Instead, the spiral channel 16 may have any suitable shape including that the spiral channel 16 may be formed from a series of rectangular, squares, triangles, irregular shapes, etc. The spiral channel 16 may be formed in any suitable manner providing that it has a progressively increasing diameter from the channel inlet 18 to the channel outlet 20. A progressively wider channel may reduce pressure drop and reduce pumping power. In the illustrated example, the spiral channel 16 formed in the cover 14 is shown as having a cylindrical cross-section. It is understood that this need not be the case and that the spiral channel 16 may be shaped in any suitable manner including that it may have a rectangular cross section.

The manifold 22 has been illustrated as having the manifold inlet 24 located on an edge periphery of the base 12 and the manifold outlet 26 located in a central portion of the base 12 and in fluid communication with the channel inlet 18. More specifically, the reservoir 28 has been illustrated as being located between the manifold outlet 26 and the channel inlet 18 and providing fluid communication between them. The manifold inlet 24 is laterally spaced from the channel outlet 20. In this manner, the base 12 and cover 14 enclose the inner contour geometry of the cold plate including the manifold 22 and the spiral channel 16.

One or more O-rings 32 may be included between the base 12 and the cover 14 to prevent leakage of liquid coolant used in the single-pass cold plate assembly 10. One or more grooves or seats 34 may be machined into the base 12 and/or the cover 14 to retain the O-rings 32. In the illustrated example, two O-Rings 32 have been included. One O-ring 32 is illustrated at an outside edge of the spiral channel 16 and the second O-ring 32 is illustrated at an edge of the reservoir 28. The O-ring around the spiral channel 16 has been illustrated as being circular while the other O-ring has been illustrated as being semi-circular. It is understood that the shape of each O-ring 32 may be configured in any suitable manner. Each may have a shape corresponding to other structures within the single-pass cold plate assembly 10 including those of the spiral channel 16 and reservoir 28.

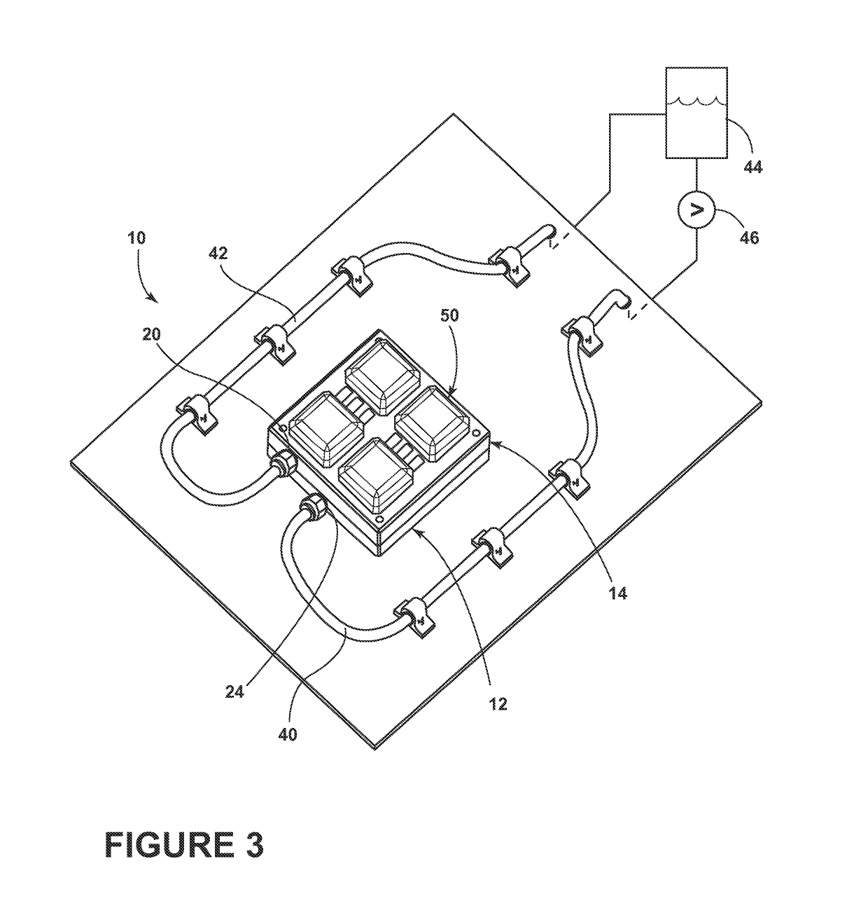

Referring now to FIG. 3, an inlet fluid line 40 and an outlet fluid line 42 have been illustrated as being fluidly coupled to the manifold inlet 24 and channel outlet 20, respectively. When the single-pass cold plate assembly 10 is assembled, the manifold inlet 24 is constructed to receive the liquid coolant and the channel outlet 20 is configured to allow the coolant to exit. The inlet fluid line 40 and outlet fluid line 42 may be fluidly coupled to a source of liquid coolant 44 and a pumping mechanism 46, both schematically illustrated, such that liquid coolant can be delivered to the manifold 22 and spiral channel 16. The inlet fluid line 40, outlet fluid line 42, source of liquid coolant 44, and pumping mechanism 46 may all be considered to be a part of the single-pass cold plate assembly 10.

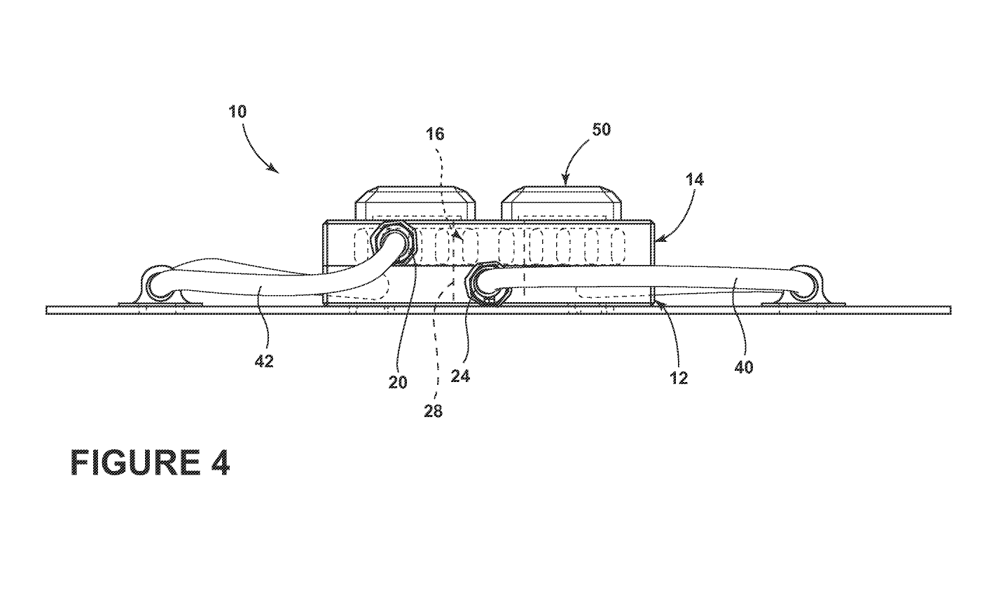

An electronic device 50 or a high-powered electronic device may be mechanically coupled to the single-pass cold plate assembly 10. The single-pass cold plate assembly 10 may be utilized with any electronic dissipating component that requires a coolant module for thermal management such as electronic components that require a uniform temperature distribution due to sensitivity with thermal expansion effects. For example, the single-pass cold plate assembly 10 may be used with both airborne and ground based electronics. In the illustrated example, the electronic device 50 has been illustrated as a metal-oxide-semiconductor field-effect transistor (MOSFET) electronic package such as silicon carbide MOSFET. The electronic device 50 has been illustrated as being mounted on a top surface of the single-pass cold plate assembly 10, which includes the spiral channel 16, in this case the cover 14, as shown in FIG. 4. The electronic device 50 may be mounted to the single-pass cold plate assembly 10 in any suitable manner including that a thermal conductive adhesive may be used to couple the single-pass cold plate assembly 10 to the electronic device to be cooled.

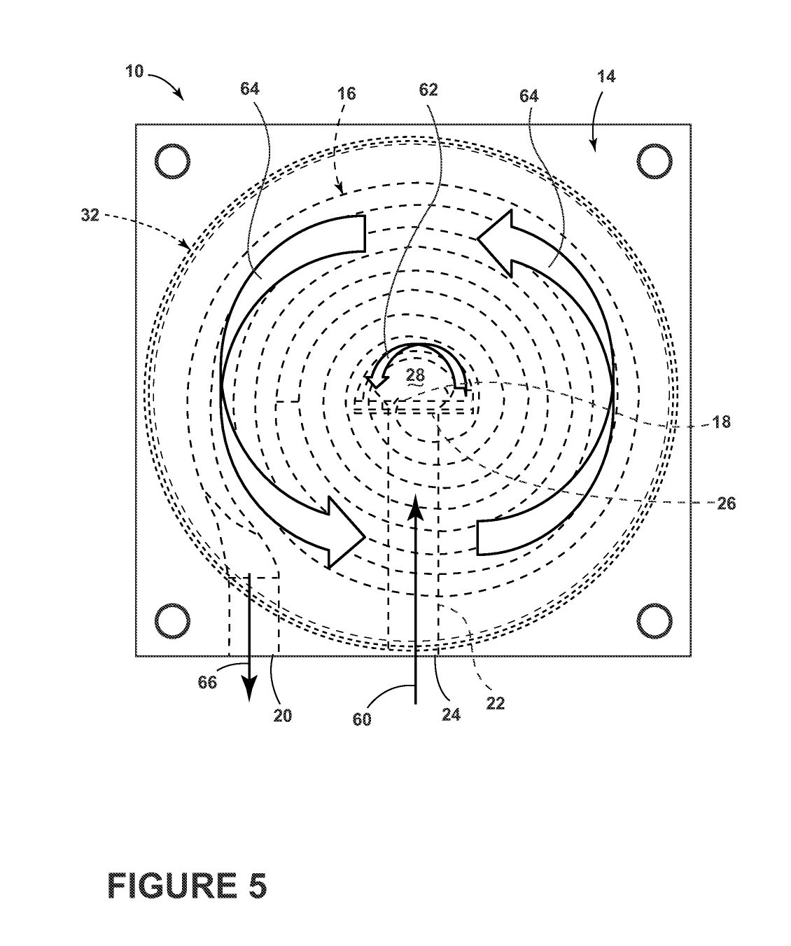

FIG. 5 illustrates the movement of the liquid coolant through the cold plate assembly 10. First, the liquid coolant enters the manifold 22 from the manifold inlet 24 as illustrated by the arrow 60. At this point, the liquid coolant has its lowest temperature and effectively removes heat from the concentrated centralized hot spot under an electronic device 50 (FIG. 4). Next, the liquid coolant flows into the central reservoir 28 as illustrated with arrow 62. The liquid coolant within the reservoir 28 maintains a low temperature at the center of the cold plate assembly 10. The liquid coolant is introduced into the reservoir 28 to minimize concentrated hot spots that are generated at the center of electronic components. The liquid coolant then enters into the spiral channel 16 as illustrated by arrows 64. The coolant within the spiral channel 16 produces an effective convection heat transfer rate while achieving a minimum pressure drop and high speed flow rate within the single-pass cold plate assembly 10. Finally, the liquid coolant flows out through the channel outlet 20 as illustrated with arrow 66.

In the above described example, within the single-pass cold plate assembly 10 fully developed turbulent flow is created because the flow path through the spiral channel 16 is long compared with the entrance diameter. In addition, there are no sharp corners within the spiral channel 16, thereby ensuring no high thermal and structural stress risers. The small radius in the spiral channel 16 minimizes fouling accumulation and maximizes the convection heat transfer coefficient. Furthermore, convection heat transfer is achieved within the single-pass cold plate assembly 10 with minimum pressure drop, since there is only one entrance and one exit hydraulic. The liquid coolant flow velocity distribution at the inlet adjusts itself to the geometry along the distance of the passage length.

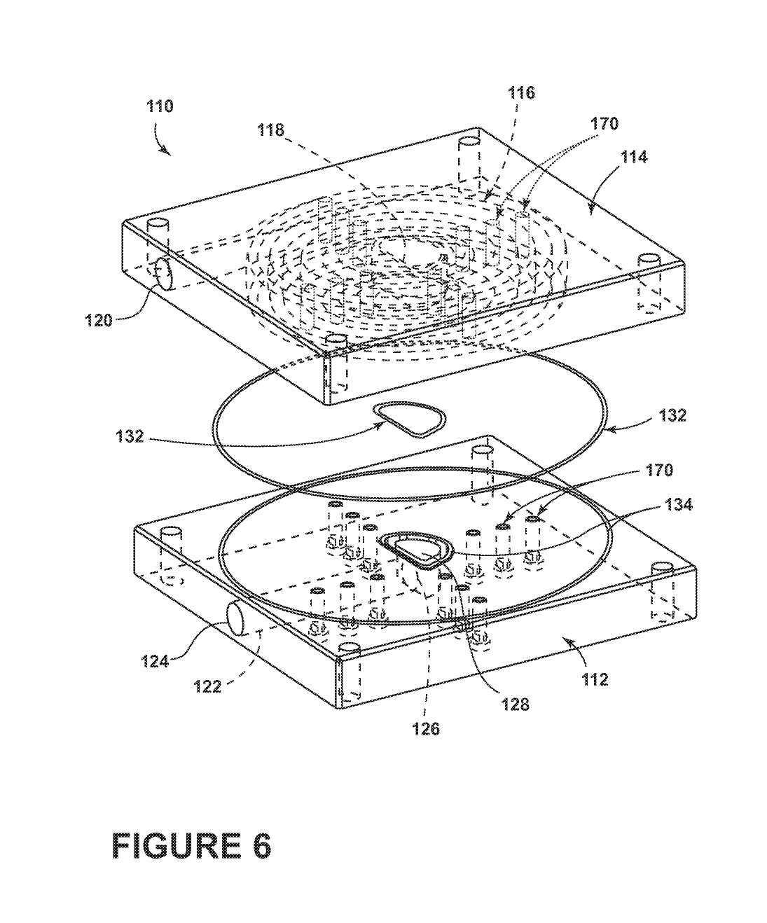

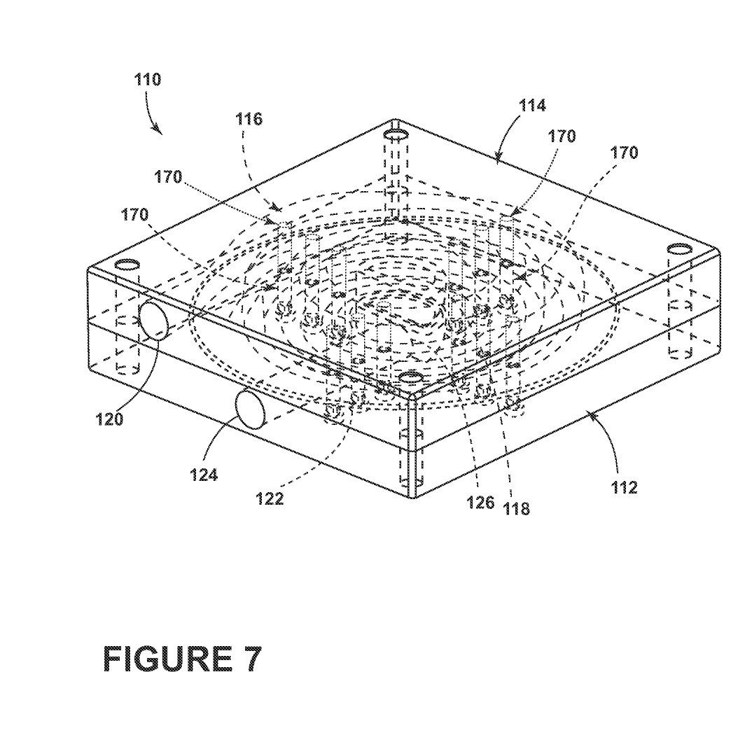

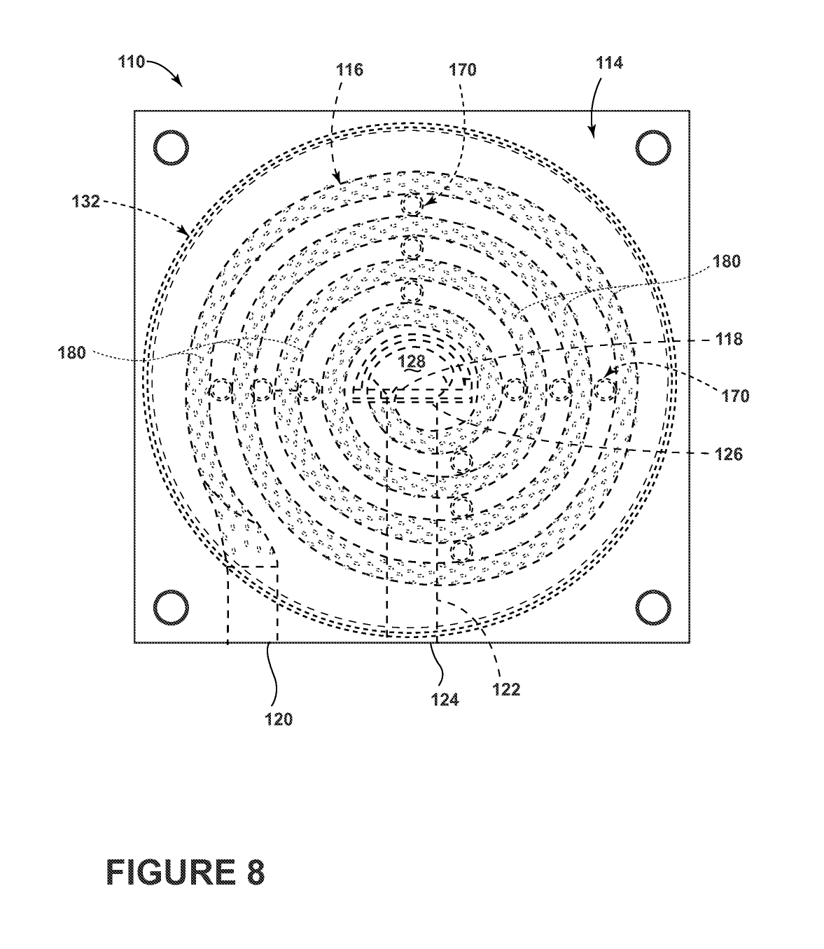

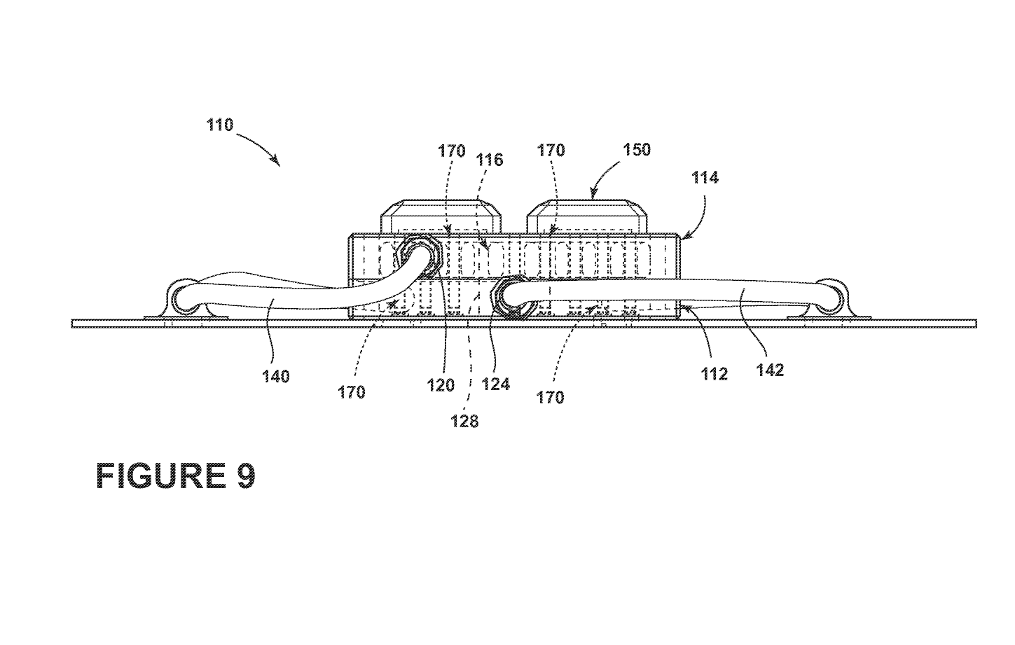

FIG. 6 illustrates an alternative single-pass cold plate assembly 110. The single-pass cold plate assembly 110 is similar to the single-pass cold plate assembly 10 previously described. Therefore, like parts will be identified with like numerals increased by 100, and it is understood that the description of like parts of the single-pass cold plate assembly 10 applies to the single-pass cold plate assembly 110, unless otherwise noted. One difference between them is that the single-pass cold plate assembly 110 includes miniature heat pipes 170 located at least partially within the spiral channel 116 to conduct heat away from hot spots located within the electronic device 150 (FIG. 9). The miniature heat pipes 170 may act as thermal vias to conduct high dissipation heat loads into the liquid coolant within the single-pass cold plate assembly 110. The miniature heat pipes 170 may be formed in any suitable manner including that a diameter of each miniature heat pipe 170 may be smaller than a length of each miniature heat pipe 170. Furthermore, the miniature heat pipes 170 may contain a phase change liquid/vapor such as water, ammonia, etc. As shown more clearly in FIGS. 7 and 8 the miniature heat pipes 170 extend through both the base 112 and cover 114.

As with the earlier described embodiment, the single-pass cold plate assembly 110 provides a high convection heat transfer coefficient to cool the electronic device 150, shown in FIG. 9. The single-pass cold plate assembly 110 may be machined of materials with the same mechanical properties as the electronic device 150, therefore matching the coefficient of thermal expansion of the electronics device 150. As with the earlier embodiment, the spiral channel 116 has a channel inlet 118 that is below the center of the electronic device 150, which provides an effective means of cooling any centrally located hot spots.

Regardless of whether the single-pass cold plate assembly includes heat pipes or not it is contemplated that the spiral channel may include riblets 180 that may project into the spiral channel. Such riblets 180 have only been schematically illustrated in FIG. 8 for illustrative purposes. The riblets 180 may be integrally formed with the spiral channel in the direction of flow of the liquid coolant. Further, such riblets 180 may project from any surface of the spiral channel including the bottom and/or sides of the spiral channel. The riblets 180 may be formed in any suitable manner to reduce pressure drop within the spiral channel including that the riblets 180 may be sized and shaped in any suitable manner. By way of non-limiting example, the riblets 180 may be on the order of 150 microns in size. Such riblets 180 may act to reduce the friction forces, reduce turbulence, and reduce the pressure drop within the single-pass cold plate assembly. By way of further alternative examples, the single-pass cold plate assembly may also be formed from additional pieces including that the single-pass cold plate assembly may include a base, cover, and a central manifold section there between. Regardless of the exact structure of the single-pass cold plate assembly, it may have a structure with a coefficient of thermal expansion that matches the electronic device that is being cooled.

The embodiments described above provide a variety of benefits including that the single-pass cold plate assemblies solve the thermal management problem of cooling electronic devices with high power dissipations. The above described embodiments provide relatively uniform cooling with an effective convection heat transfer coefficient and have a large area coupling the cooling medium to the electronic device being cooled. Compared with contemporary heat exchangers such as a milli-channel heat exchanger, the above described embodiments provide an order of magnitude lower manufacturing cost, a three times more effective cooling means, lower manufacturing and operational induced stresses and two times lower fluid flow pressure drop. The above described embodiments may be manufactured rapidly and at low cost. Further, during production, the simplicity of parts allows ease of assembly. The above described embodiments have a lower heat sink volume and have a lower required pump pressure when compared to a conventional heat exchanger with internal fins, which minimizes pump electrical draw. The above described embodiments are also light weight, have a high thermal efficiency, and improved component reliability.

To the extent not already described, the different features and structures of the various embodiments may be used in combination with each other as desired. Some features may not be illustrated in all of the embodiments, but may be implemented if desired. Thus, the various features of the different embodiments may be mixed and matched as desired to form new embodiments, whether or not the new embodiments are expressly described. All combinations or permutations of features described herein are covered by this disclosure.

This written description uses examples to disclose the invention, including the best implementation, to enable any person skilled in the art to practice the invention, including making and using the devices or systems described and performing any incorporated methods presented. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A single-pass cold plate assembly comprising:
a base and a cover arranged in confronting relationship to define a cold plate;
a spiral channel having at least a portion provided in one of the base and cover, with a channel inlet located in a central portion of the one of the base and cover, and a channel outlet located at a periphery of the one of the base and cover; and
a manifold provided in the other of the base and cover, with the manifold having a manifold inlet located on a periphery of the other of the base and cover, and a manifold outlet located in a central portion of the other of the base and cover and in fluid communication with the channel inlet;
wherein liquid coolant introduced into the manifold inlet may travel through the manifold, out the manifold outlet, into the channel inlet, where it moves through the spiral channel and out the channel outlet to complete a single pass through the cold plate assembly.

2. The single-pass cold plate assembly of claim 1 wherein the base and cover are each circular, square, or rectangular.

3. The single-pass cold plate assembly of claim 1 wherein the spiral channel has a progressively increasing diameter from the inlet to the outlet.

4. The single-pass cold plate assembly of claim 1 wherein at least a portion of the spiral channel has a cylindrical cross-section.

5. The single-pass cold plate assembly of claim 1, further comprising riblets projecting into the spiral channel.

6. The single-pass cold plate assembly of claim 5 wherein the riblets are integrally formed with the spiral channel in a direction of a liquid coolant flow.

7. The single-pass cold plate assembly of claim 5 wherein the riblets project from a bottom and sides of the spiral channel.

8. The single-pass cold plate assembly of claim 5 wherein the riblets are on the order of 150 microns in size.

9. The single-pass cold plate assembly of claim 1 wherein the manifold inlet is laterally spaced from the channel outlet.

10. The single-pass cold plate assembly of claim 9, wherein the manifold inlet is on an edge periphery of the one of the base and cover.

11. The single-pass cold plate assembly of claim 10 wherein the channel outlet is on an edge periphery of the other of the base and cover.

12. The single-pass cold plate assembly of claim 1, further comprising a reservoir between the manifold outlet and the channel inlet.

13. The single-pass cold plate assembly of claim 1, further comprising miniature heat pipes located within the spiral channel to conduct the heat away from an electronic device.

14. The single-pass cold plate assembly of claim 13 wherein a diameter of each miniature heat pipe is smaller than a length of each miniature heat pipe.

15. The single-pass cold plate assembly of claim 1 wherein a thermally conductive adhesive is used to couple the cold plate to a high-powered electronics device to be cooled.
